(19) United States
(12) Patent Application Publication
(10) Pub. No.: US 2004/0100337 A1
(43) Pub. Date: May 27, 2004

(54) IC oscillation frequnecy internal drive control

(76) Inventors: Kuo-Chang Wang, Hsin Chu City (TW); Ching-Hung Tseng, Hsin Chu City (TW)

Correspondence Address: KUO-CHANG WANG, P.O. BOX 7-820, TAIPEI, TW

(21) Appl. No.: 10/300,965

(22) Filed: Nov. 22, 2002

(51) Int. Cl. H03B 1/00

(52) U.S. Cl. 331/74

(57) ABSTRACT

An IC oscillation frequency internal drive control characterized by that a record unit being provided at the front end of the oscillator of the IC circuit; the record unit including multiple recordable points and a safe recordable point; the front end of the record unit being connected in series with an internal record control circuit to receive signals inputted from an external circuit or software; oscillation frequency being outputted from the rear end of the oscillator to control the internal record control circuit by external signals thus to designate various recordable points to drive and control the oscillator to generate various oscillation frequencies to be transmitted back to the external circuit or software for performing in time self feedback in cycles to detect recording of the optimal drive oscillation recordable points, finally to achieve easy control of safe and constant outputs of working frequencies that are applicable to various electronic peripherals.

### BACKGROUND OF THE INVENTION

1. Field of the Invention

The present invention relates to an apparatus for automatically selecting internal or external resistor, characterized by that a built-in control unit is placed in front of the oscillator of the integrated circuit, and such control unit comprises a detection circuit for coupling the external resistor and oscillator, and an internal resistor bridging the detection circuit in parallel with its output end, such that the detection circuit can automatically detect whether or not there is any input of serial signal from the external resistor to switch into the external or internal resistor at appropriate time, and further select inputting the optimal operating frequency of the control IC.

2. Description of the Prior Art

In general, the consumption IC chips are widely used in all types of products. To cater for different use of program and devices such as hardware, manufacturers usually uses a single pin of the IC to externally connect the resistor on hardware peripherals, and adjust or set the IC operating frequency to drive the device. Therefore, it is essential to operate the related operation frequency of the externally connected resistor. To adopt the diversified frequencies required by different manufacturers, the prior art makes use of the other pin of the integrated circuit to cross connect with another set of resistor, so as to process the distinction, selection and switch to the appropriate frequency. Such additional pin will finally increase the bearing cost of the related components and thus become a waste as economical trouble.

### SUMMARY OF THE INVENTION

The primary purpose of the present invention is to provide an IC oscillation frequency internal drive control essentially comprised of a record unit and an internal record control circuit connected in series before an IC circuit to perform self-test and record the optimal recordable point for driving an oscillator to achieve safe and constant output for easy control of various electronic peripheral working frequencies.

Another purpose of the present invention is to provide an IC oscillation frequency internal drive control that the front end of the internal record control circuit is provided for receiving signals inputted from an external circuit or software to control the circuit for designating various recordable points inside the record unit to drive and control the oscillator to generate various output oscillation frequencies for operation.

Another purpose yet of the present invention is to provide an IC oscillation frequency internal drive control that further includes a safe recordable point in the record unit to allow the IC self-feed back for testing and recording the optimal recordable point before separately recording the safe recordable point to prevent the function of the optimal recordable point from being changed.

### BRIEF DESCRIPTION OF THE DRAWINGS

FIG. 1 is a block chart of a circuit of a preferred embodiment of the present invention;

FIGS. 2 and 3 are block charts of a circuit of another preferred embodiment of the present invention.

### DETAILED DESCRIPTION OF THE PREFERRED EMBODIMENT

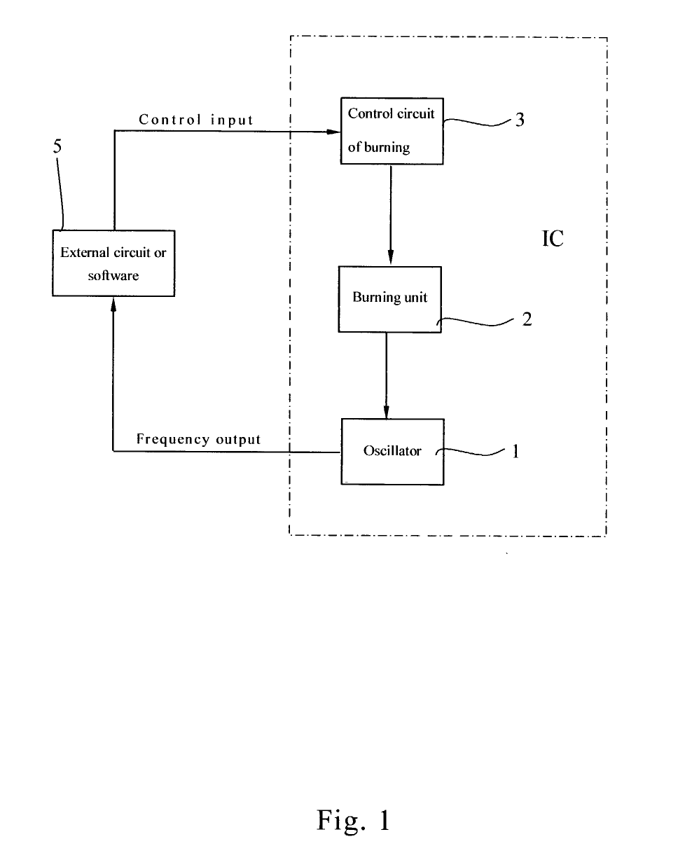

Referring to FIG. 1, a preferred embodiment of the present invention is essentially comprised of a record unit 2 that is provided at the front end of an oscillator 1 inside an IC circuit. The record unit 2 includes multiple recordable points and a safe recordable point (a point survives recording by conventional ploy/metal/flash/EEPROM/OTP . . . facilities) and an internal record control circuit 3 connected in series before the record unit 2. Wherein, the internal record control circuit 3 receives signals inputted from an external circuit 5 or software for selected output to determine recordable points and non-recordable points inside the record unit 2, and then respectively record and store those recordable points with external input control values; thus to further drive the oscillator 1 to generate various oscillation frequency outputs. Meanwhile, the output frequency is fed back to the external circuit 5 or the software to read at any time the latest output oscillation values, which then are compared with the existing values to update data and input oscillation values that are comparatively applicable to an external peripheral device into the internal record control circuit 3, so to modify in time for recording the optimal drive recordable point to generate highly constant oscillation frequency. Furthermore, the safe recordable point inside the record unit 2 is repeatedly modified by the feedback until it carries the optimal frequency and the safe recordable point with the optimal frequency is immediately recorded to make sure that other recordable points will not be modified once again, thus are capable of performing self-feed back in cycles to test, record and protect the optimal recordable point to drive the oscillator, thus to achieve easy control of safe and constant outputs that are applicable to the working frequency of various electronic peripherals.

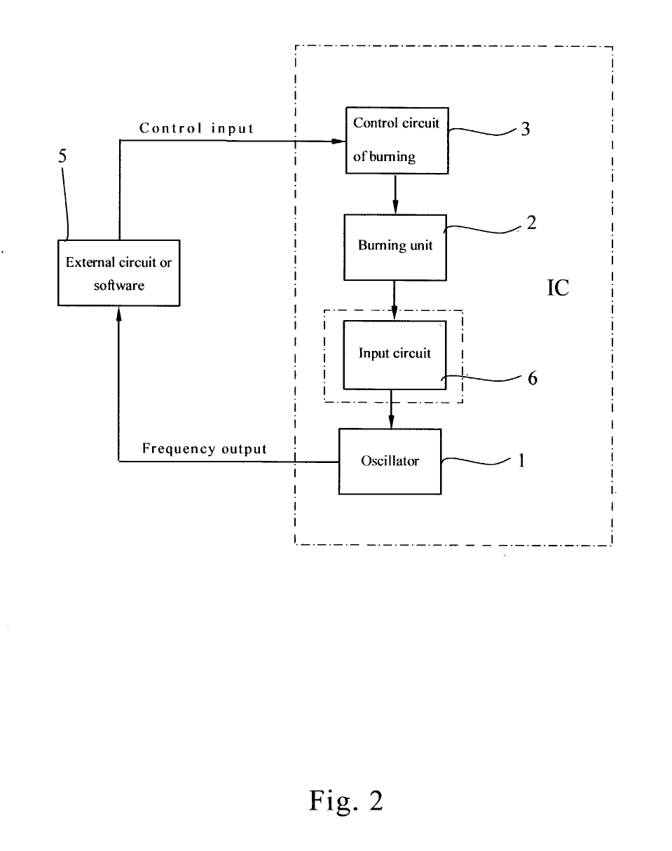

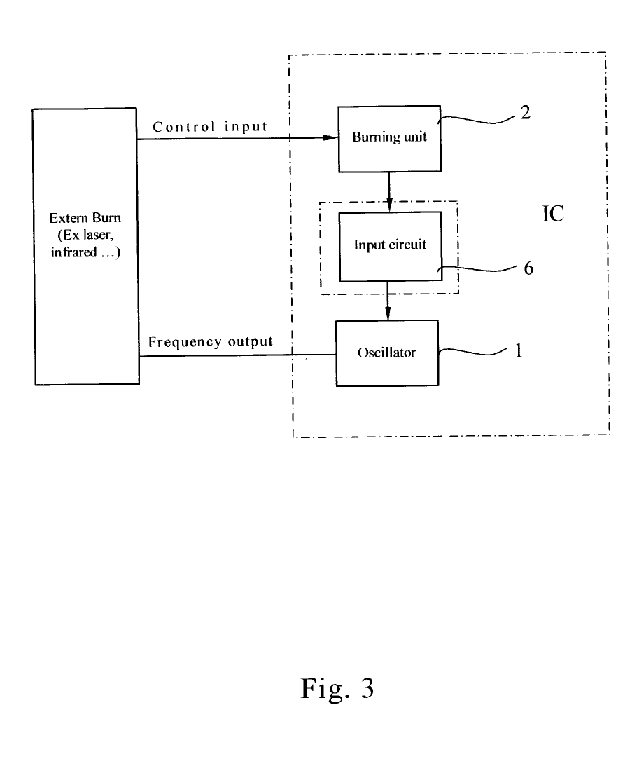

Referring to FIGS. 2 and 3, wherein, a general input circuit 6 is separately-connected in series between the IC oscillator and the record unit for additional inputs to control the oscillator; or, alternatively, the internal record control circuit 3 is omitted, instead, signals are forthwith externally inputted using technologies including laser or infrared to change those internal recordable points in the record unit 2, thus to create the equivalent control efficacy of various oscillation frequency outputs.

While the invention has been described by means of specific embodiments, numerous modifications and variations could be made thereto by those skilled in the art without departing from the scope and spirit of the invention set forth in the claims.

What is claimed is:

1. An IC oscillation frequency internal drive control is essentially comprised of a record unit and an internal record control circuit being connected in series at the front end of an IC oscillator; wherein,
the record unit including multiple recordable points and a safe recordable point (a point survives recording by conventional ploy/metal/flash/EEPROM/OTP . . . facilities); those multiple recordable points being provided to receive, record and store output control values from the internal record control circuit at the front end of the oscillator while the safe recordable point being separately recorded to prevent other recordable points from being further modified; and
the internal record control circuit having at its front end to receive signals inputted from an external circuit or software for selected output control for determining which are recordable and which are non-recordable in the record unit at its rear end; characterized by that:
those externally inputted control values being respectively recorded and stored to drive the oscillation; feedbacks from the oscillation frequency generated being outputted to the external circuit or software to read updated data for modifying the oscillation frequency that is comparatively applicable for record points from an externally provided device to generate highly constant oscillation frequency, and further to perform self feedback in cycles to test and record and protect the optimal record point to drive the oscillator, thus to achieve easy control of safe and constant outputs that are applicable to the working frequency of various electronic peripherals.

2. An IC oscillation frequency internal drive control as claimed in claim 1, wherein, a general input circuit is separately connected in series between the IC oscillator and the record unit to provide additional inputs to control the oscillator.

3. An IC oscillation frequency internal drive control as claimed in claim 1 or claim 2, wherein, the internal record control circuit is omitted and instead, external means including laser, infrared or similar technologies are used to forthwith input signals to change the internal record points in the record unit thus to produce the equivalent record control.
